(19) United States
(12) Patent Application Publication
(10) Pub. No.: US 2024/0243046 A1
(43) Pub. Date: Jul. 18, 2024

(54) FLIP CHIP BALL GRID ARRAY PACKAGE

(71) Applicant: MEDIATEK INC., Hsin-Chu (TW)

(72) Inventors: Chun-Yin Lin, Hsinchu City (TW); Tai-Yu Chen, Hsinchu City (TW); Li-Song Lin, Hsinchu City (TW); Chi-Yuan Chen, Hsinchu City (TW)

(73) Assignee: MEDIATEK INC., Hsin-Chu (TW)

(21) Appl. No.: 18/402,667

(22) Filed: Jan. 2, 2024

Related U.S. Application Data
(60) Provisional application No. 63/480,321, filed on Jan. 18, 2023.

(51) Int. Cl. H01L 23/498; H01L 23/00; H01L 23/373

(52) U.S. Cl. CPC H01L 23/49816; H01L 23/3735; H01L 23/49822; H01L 24/08; H01L 24/16; H01L 2224/08145; H01L 2224/08225; H01L 2224/16225; H01L 2224/16227; H01L 2924/01013; H01L 2924/01029; H01L 2924/15311; H01L 2924/18161; H01L 2924/351

(57) ABSTRACT

A flip chip ball grid array package includes a package substrate and a flip chip device mounted on a top surface of the package substrate. The flip chip device includes a semiconductor integrated circuit die; an epoxy molding compound encapsulating vertical sidewalls of the semiconductor integrated circuit die; a re-distribution layer structure disposed on an active surface of the semiconductor integrated circuit die and on a lower surface of the epoxy molding compound; a sintered nanosilver layer disposed on a passive rear surface of the semiconductor integrated circuit die and on an upper surface of the epoxy molding compound; and a stiffener ring mounted around the flip chip device on the package substrate.

### CROSS REFERENCE TO RELATED APPLICATIONS

This application claims the benefit of U.S. Provisional Application No. 63/480,321, filed on Jan. 18, 2023. The content of the application is incorporated herein by reference.

### BACKGROUND

Ball grid array (BGA) is a type of integrated circuit packaging technology which is characterized by the use of a substrate whose upper surface is mounted with a semiconductor chip and whose lower surface is mounted with a grid array of solder balls. During a surface mount technology process, for example, the BGA package can be mechanically bonded and electrically coupled to a printed circuit board (PCB) by the grid array of solder balls.

Flip Chip Ball Grid Array (FCBGA) is a type of BGA technology that uses flip chip technology in mounting the active side of the chip die in an upside-down manner over the substrate and bonded to the substrate by the use of solder bumps attached to the input/output (I/O) pads of the die. A ring-type FCBGA includes a stiffener ring mounted on the upper surface of the substrate.

For the high-performance computing (HPC) applications, ring-type FCBGA has the advantages of higher reliability, lower package stress and better thermal performance because of the elimination of the thermal interface material (TIM1) thermal resistance. As the die size becomes smaller, the thermal problem such as high power density or local hotspot issues becomes problematic.

### SUMMARY

It is one object of the present disclosure to provide an improved semiconductor package in order to solve the prior art deficiencies or shortcomings.

One aspect of the invention provides a flip chip ball grid array package including a package substrate and a flip chip device mounted on a top surface of the package substrate. The flip chip device includes a semiconductor integrated circuit die; an epoxy molding compound encapsulating vertical sidewalls of the semiconductor integrated circuit die; a re-distribution layer structure disposed on an active surface of the semiconductor integrated circuit die and on a lower surface of the epoxy molding compound; a sintered nanosilver layer disposed on a passive rear surface of the semiconductor integrated circuit die and on an upper surface of the epoxy molding compound; and a stiffener ring mounted around the flip chip device on the package substrate.

According to some embodiments, the passive rear surface of the semiconductor integrated circuit die is not covered by the epoxy molding compound.

According to some embodiments, the passive rear surface of the semiconductor integrated circuit die is in thermal contact with the sintered nanosilver layer.

According to some embodiments, the epoxy molding compound occupies 10-20% of a surface area of the flip chip device when viewed from above.

According to some embodiments, the flip chip device is attached to contact pads on the top surface of the package substrate using solder bumps.

According to some embodiments, underfill is disposed between semiconductor integrated circuit die and the package substrate.

According to some embodiments, the stiffener ring comprises an aluminum ring or a copper ring.

According to some embodiments, the sintered nanosilver layer is adhered to the passive rear surface of the semiconductor integrated circuit die and the upper surface of the epoxy molding compound by using a material layer with high thermal conductivity.

According to some embodiments, the material layer with high thermal conductivity comprises thermal interface material (TIM1), metals, graphene, or silver adhesive paste.

According to some embodiments, the flip chip ball grid array package further includes solder balls attached to contact pads on a bottom surface of the package substrate.

Another aspect of the invention provides a flip chip ball grid array package including a package substrate and a flip chip device mounted on a top surface of the package substrate. The flip chip device includes a semiconductor integrated circuit die; an epoxy molding compound encapsulating vertical sidewalls of the semiconductor integrated circuit die; a re-distribution layer structure disposed on an active surface of the semiconductor integrated circuit die and on a lower surface of the epoxy molding compound; a sintered nanosilver layer disposed on a passive rear surface of the semiconductor integrated circuit die and on an upper surface of the epoxy molding compound; and a lid mounted on the package substrate. The lid is in direct contact with the sintered nanosilver layer.

According to some embodiments, the passive rear surface of the semiconductor integrated circuit die is not covered by the epoxy molding compound.

According to some embodiments, the passive rear surface of the semiconductor integrated circuit die is in thermal contact with the sintered nanosilver layer.

According to some embodiments, the epoxy molding compound occupies 10-20% of a surface area of the flip chip device when viewed from above.

According to some embodiments, the flip chip device is attached to contact pads on the top surface of the package substrate using solder bumps.

According to some embodiments, underfill is disposed between semiconductor integrated circuit die and the package substrate.

According to some embodiments, the lid comprises metals, metal alloys, or polymers.

According to some embodiments, the sintered nanosilver layer is adhered to the passive rear surface of the semiconductor integrated circuit die and the upper surface of the epoxy molding compound by using a material layer with high thermal conductivity.

According to some embodiments, the material layer with high thermal conductivity comprises thermal interface material (TIM1), metals, graphene, or silver adhesive paste.

According to some embodiments, the flip chip ball grid array package further includes solder balls attached to contact pads on a bottom surface of the package substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings:

FIG. 1 is a schematic, cross-sectional diagram showing a flip chip ball grid array package (FCBGA) package in accordance with an embodiment of the invention; and

FIG. 2 is a schematic, cross-sectional diagram showing a FCBGA package in accordance with another embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

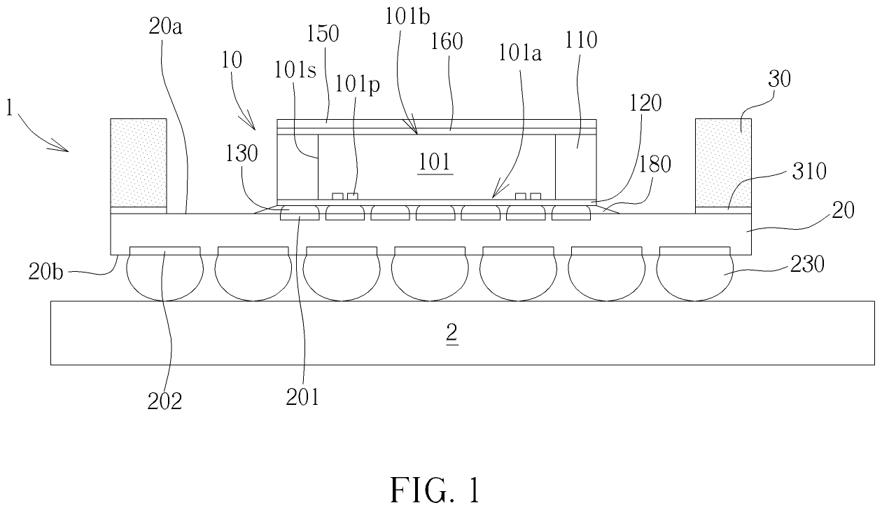

FIG. 1 is a schematic, cross-sectional diagram showing a flip chip ball grid array package (FCBGA) package 1 in accordance with an embodiment of the invention. As shown in FIG. 1, the FCBGA package 1 comprises a flip chip device 10 including, but not limited to, a semiconductor integrated circuit (IC) die 101, an epoxy molding compound 110 encapsulating vertical sidewalls 101s of the semiconductor integrated circuit die 101, a re-distribution layer (RDL) structure 120 disposed on an active surface 101a of the semiconductor integrated circuit die 101 and on a lower surface of the epoxy molding compound 110 to fan out the input/output (I/O) pads 101p on the active surface 101a of the semiconductor integrated circuit die 101, and a sintered nanosilver layer 150 disposed on a passive rear surface 101b of the semiconductor integrated circuit die 101 and on an upper surface of the epoxy molding compound 110.

According to an embodiment, for example, the sintered nanosilver layer 150 may be formed by sintering silver nanoparticles at a relatively low temperature and may have excellent thermal characteristics. In some embodiments, optionally, the sintered nanosilver layer 150 may be adhered to the passive rear surface 101b of the semiconductor integrated circuit die 101 and the upper surface of the epoxy molding compound 110 by using a material layer 160 with high thermal conductivity, including, but not limited to, thermal interface material (TIM1), metals, graphene, or silver adhesive paste.

According to an embodiment, the passive rear surface 101b of the semiconductor integrated circuit die 101 is not covered by the epoxy molding compound 110, and therefore the passive rear surface 101b of the semiconductor integrated circuit die 101 is in thermal contact with the sintered nanosilver layer 150. The epoxy molding compound 110 can improve the heat transfer capability and enhance the structural strength of the flip chip device 10. According to an embodiment, the epoxy molding compound 110 may occupy 10-20% of the surface area of the flip chip device 10 when viewed from the above.

According to an embodiment, the flip chip device 10 is attached to contact pads 201 on a top surface 20a of the underlying package substrate 20 using solder bumps 130. Optionally, underfill 180 may be used between semiconductor integrated circuit die 101 and the package substrate 20 to provide adhesion to help protect semiconductor integrated circuit die 101 from separating from the package substrate 20.

According to an embodiment, a stiffener ring 30 is mounted around the flip chip device 10 on the package substrate 20 using adhesive 310 and is spaced apart from the flip chip device 10. According to an embodiment, the stiffener ring 30 maybe an aluminum ring or a copper ring, but is not limited thereto. According to an embodiment, the stiffener ring 30 may comprise metals, metal alloys, polymers or any suitable materials known in the art. According to an embodiment, optionally, a heat sink (not shown) may be mounted on top of the sintered nanosilver layer 150 of the FCBGA package 1.

According to an embodiment, solder balls 230 such as ball grid array (BGA) balls may be attached to contact pads 202 on the bottom surface 20b of the package substrate 20 to provide electrical contact with and attachment of FCBGA package 1 to a system board or a printed circuit board (PCB) 2.

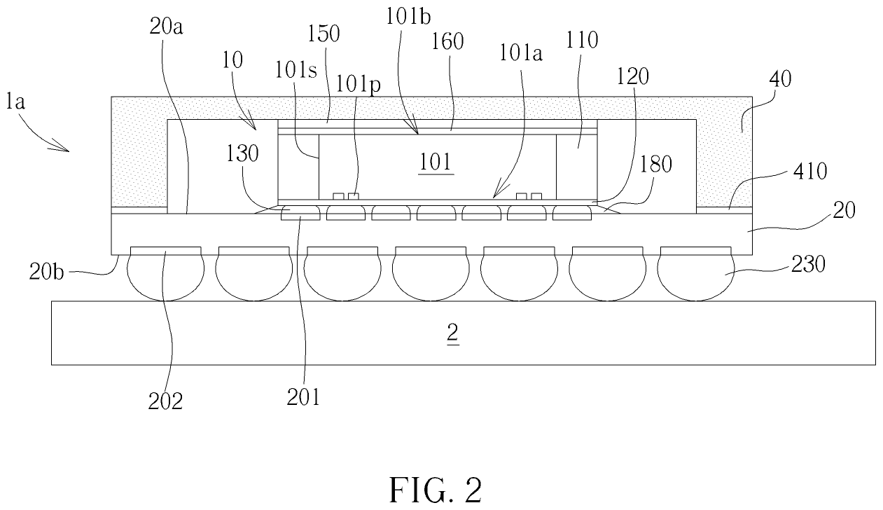

FIG. 2 is a schematic, cross-sectional diagram showing a flip chip ball grid array package (FCBGA) package 1a in accordance with another embodiment of the invention, wherein like regions, layers or elements are designated by like numeral numbers or labels. As shown in FIG. 2, likewise, the FCBGA package 1a comprises a flip chip device 10 including, but not limited to, a semiconductor integrated circuit die 101, an epoxy molding compound 110 encapsulating vertical sidewalls 101s of the semiconductor integrated circuit die 101, a re-distribution layer structure 120 disposed on an active surface 101a of the semiconductor integrated circuit die 101 and on a lower surface of the epoxy molding compound 110 to fan out the input/output pads 101p on the active surface 101a of the semiconductor integrated circuit die 101, and a sintered nanosilver layer 150 disposed on a passive rear surface 101b of the semiconductor integrated circuit die 101 and on an upper surface of the epoxy molding compound 110.

According to an embodiment, for example, the sintered nanosilver layer 150 may be formed by sintering silver nanoparticles at a relatively low temperature and may have excellent thermal characteristics. In some embodiments, optionally, the sintered nanosilver layer 150 may be adhered to the passive rear surface 101b of the semiconductor integrated circuit die 101 and the upper surface of the epoxy molding compound 110 by using a material layer 160 with high thermal conductivity, including, but not limited to, thermal interface material (TIM1), metals, graphene, or silver adhesive paste.

According to an embodiment, the passive rear surface 101b of the semiconductor integrated circuit die 101 is not covered by the epoxy molding compound 110, and therefore the passive rear surface 101b of the semiconductor integrated circuit die 101 is in thermal contact with the sintered nanosilver layer 150. The epoxy molding compound 110 can improve the heat transfer capability and enhance the structural strength of the flip chip device 10. According to an embodiment, the epoxy molding compound 110 may occupy 10-20% of the surface area of the flip chip device 10 when viewed from the above.

According to an embodiment, the flip chip device 10 is attached to contact pads 201 on a top surface 20a of the underlying package substrate 20 using solder bumps 130. Optionally, underfill 180 may be used between semiconductor integrated circuit die 101 and the package substrate 20 to provide adhesion to help protect semiconductor integrated circuit die 101 from separating from the package substrate 20.

According to an embodiment, a lid 40 is mounted on the package substrate 20 using adhesive 410 and is in direct contact with the sintered nanosilver layer 150 of the flip chip device 10. According to an embodiment, the lid 40 may comprise metals, metal alloys, polymers or any suitable materials known in the art. According to an embodiment, optionally, a heat sink (not shown) may be mounted on top of the lid 40 of the FCBGA package 1a.

According to an embodiment, solder balls 230 such as ball grid array (BGA) balls may be attached to contact pads 202 on the bottom surface 20b of the package substrate 20 to provide electrical contact with and attachment of FCBGA package 1a to a system board or a printed circuit board.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flip chip ball grid array package, comprising:
a package substrate; and
a flip chip device mounted on a top surface of the package substrate, wherein the flip chip device comprises a semiconductor integrated circuit die; an epoxy molding compound encapsulating vertical sidewalls of the semiconductor integrated circuit die; a re-distribution layer structure disposed on an active surface of the semiconductor integrated circuit die and on a lower surface of the epoxy molding compound; a sintered nanosilver layer disposed on a passive rear surface of the semiconductor integrated circuit die and on an upper surface of the epoxy molding compound; and a stiffener ring mounted around the flip chip device on the package substrate.

2. The flip chip ball grid array package according to claim 1, wherein the passive rear surface of the semiconductor integrated circuit die is not covered by the epoxy molding compound.

3. The flip chip ball grid array package according to claim 1, wherein the passive rear surface of the semiconductor integrated circuit die is in thermal contact with the sintered nanosilver layer.

4. The flip chip ball grid array package according to claim 1, wherein the epoxy molding compound occupies 10-20% of a surface area of the flip chip device when viewed from above.

5. The flip chip ball grid array package according to claim 1, wherein the flip chip device is attached to contact pads on the top surface of the package substrate using solder bumps.

6. The flip chip ball grid array package according to claim 1, wherein underfill is disposed between semiconductor integrated circuit die and the package substrate.

7. The flip chip ball grid array package according to claim 1, wherein the stiffener ring comprises an aluminum ring or a copper ring.

8. The flip chip ball grid array package according to claim 1, wherein the sintered nanosilver layer is adhered to the passive rear surface of the semiconductor integrated circuit die and the upper surface of the epoxy molding compound by using a material layer with high thermal conductivity.

9. The flip chip ball grid array package according to claim 8, wherein the material layer with high thermal conductivity comprises thermal interface material (TIM1), metals, graphene, or silver adhesive paste.

10. The flip chip ball grid array package according to claim 1 further comprising:
solder balls attached to contact pads on a bottom surface of the package substrate.

11. A flip chip ball grid array package, comprising:
a package substrate; and
a flip chip device mounted on a top surface of the package substrate, wherein the flip chip device comprises a semiconductor integrated circuit die; an epoxy molding compound encapsulating vertical sidewalls of the semiconductor integrated circuit die; a re-distribution layer structure disposed on an active surface of the semiconductor integrated circuit die and on a lower surface of the epoxy molding compound; a sintered nanosilver layer disposed on a passive rear surface of the semiconductor integrated circuit die and on an upper surface of the epoxy molding compound; and a lid mounted on the package substrate, wherein the lid is in direct contact with the sintered nanosilver layer.

12. The flip chip ball grid array package according to claim 11, wherein the passive rear surface of the semiconductor integrated circuit die is not covered by the epoxy molding compound.

13. The flip chip ball grid array package according to claim 11, wherein the passive rear surface of the semiconductor integrated circuit die is in thermal contact with the sintered nanosilver layer.

14. The flip chip ball grid array package according to claim 11, wherein the epoxy molding compound occupies 10-20% of a surface area of the flip chip device when viewed from above.

15. The flip chip ball grid array package according to claim 11, wherein the flip chip device is attached to contact pads on the top surface of the package substrate using solder bumps.

16. The flip chip ball grid array package according to claim 11, wherein underfill is disposed between semiconductor integrated circuit die and the package substrate.

17. The flip chip ball grid array package according to claim 11, wherein the lid comprises metals, metal alloys, or polymers.

18. The flip chip ball grid array package according to claim 11, wherein the sintered nanosilver layer is adhered to the passive rear surface of the semiconductor integrated circuit die and the upper surface of the epoxy molding compound by using a material layer with high thermal conductivity.

19. The flip chip ball grid array package according to claim 18, wherein the material layer with high thermal conductivity comprises thermal interface material (TIM1), metals, graphene, or silver adhesive paste.

20. The flip chip ball grid array package according to claim 11 further comprising:
solder balls attached to contact pads on a bottom surface of the package substrate.
